(19) United States
(12) Patent Application Publication
(10) Pub. No.: US 2014/0217874 A1
(43) Pub. Date: Aug. 7, 2014

(54) TOUCH-SENSITIVE DEVICE AND CONTROL METHOD THEREOF

(71) Applicant: HON HAI PRECISION INDUSTRY CO., LTD., New Taipei (TW)

(72) Inventors: TAY-YANG LIN, New Taipei (TW); CHIN-FENG CHEN, New Taipei (TW); SHU-MING LIU, New Taipei (TW); CHIA-JUNG LIU, New Taipei (TW); YI-RU LAI, New Taipei (TW); PO-SUNG CHUANG, New Taipei (TW)

(73) Assignee: HON HAI PRECISION INDUSTRY CO., LTD., New Taipei (TW)

(21) Appl. No.: 14/161,645

(22) Filed: Jan. 22, 2014

(30) Foreign Application Priority Data
Feb. 4, 2013 (TW) 102104266

(51) Int. Cl. H05K 5/02

(52) U.S. Cl. CPC H05K 5/0221
USPC 312/326; 292/251.5

(57) ABSTRACT

An electronic device includes a cover member rotatably connected to a base member. A magnetic lock is located on a working surface of the base member. A touch-sensitive bar is located on a side surface of the base member. When the cover member and the base member are closed, the magnetic lock provides a magnetic attraction between the cover member and the base member. When the touch-sensitive bar detects a touch gesture input by a user and the touch gesture matches a predefined touch gesture, the magnetic lock releases the magnetic attraction between the cover member and the base member.

### REFERENCE TO RELATED APPLICATIONS

This application claims all benefits accruing under 35 U.S.C. §119 from Taiwan Patent Application No. 102104266, filed on Feb. 4, 2013 in the Taiwan Intellectual Property Office. The contents of the Taiwan Application are hereby incorporated by reference.

### BACKGROUND

1. Technical Field

The disclosure generally relates to electronic devices, and particularly relates to touch-sensitive devices and methods for controlling a touch-sensitive device.

2. Description of Related Art

A portable computing device such as a notebook computer, includes a cover member (or a display member) pivotally connected to a base member. When the device is not in use, the cover member and the base member are closed for protection purposes. When a user wants to use the device, the user needs to open the device by rotating the cover member relative to the base member. However, the conventional method of opening the device is inconvenient and archaic.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is a schematic view of one embodiment of an electronic device.

FIG. 2 is a block diagram of one embodiment of the electronic device of FIG. 1.

FIG. 3 is a schematic view of the electronic device of FIG. 1 in a closed state.

FIG. 4 is a schematic view of the electronic device of FIG. 1 being opened by a right-to-left slide touch.

FIG. 5 is a schematic view of the electronic device of FIG. 1 being opened by a left-to-right slide touch.

FIG. 6 is a schematic view of one embodiment of the electronic device of FIG. 1 being opened by two simultaneous slide touches.

FIG. 7 is a schematic view of another embodiment of the electronic device of FIG. 1 being opened by two simultaneous slide touches.

FIG. 8 is a flowchart of one embodiment of a method for controlling the electronic device of FIG. 1.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one.”

In general, the word “module,” as used herein, refers to logic embodied in hardware or firmware, or to a collection of software instructions, written in a programming language such as Java, C, or assembly. One or more software instructions in the modules may be embedded in firmware, such as in an erasable-programmable read-only memory (EPROM). The modules described herein may be implemented as either software and/or hardware modules and may be stored in any type of non-transitory computer-readable medium or other storage device. Some non-limiting examples of non-transitory computer-readable media are compact discs (CDs), digital versatile discs (DVDs), Blu-Ray discs, Flash memory, and hard disk drives.

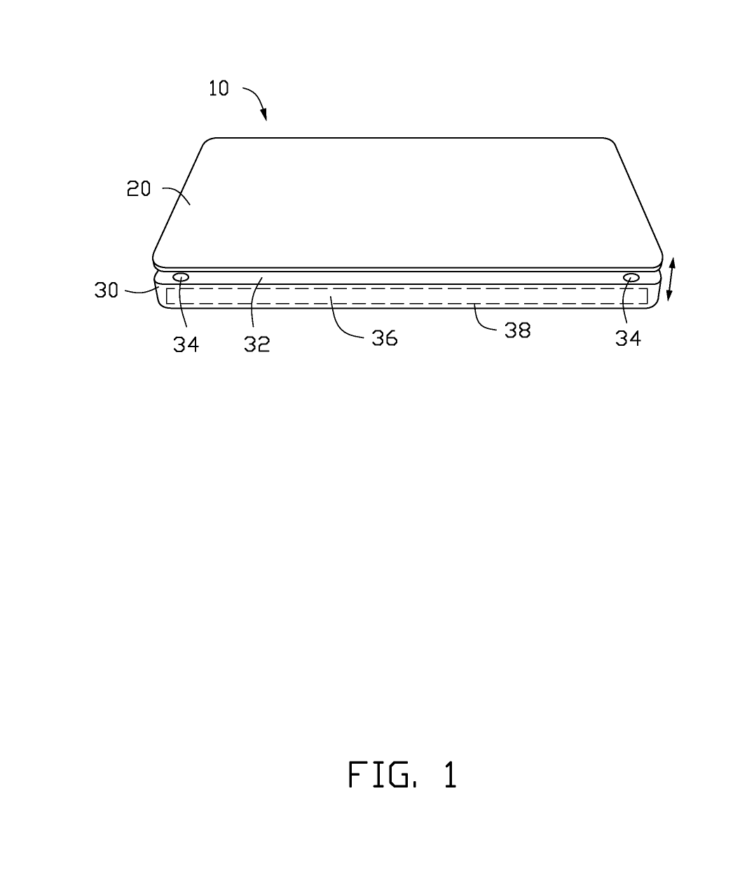

FIG. 1 shows an embodiment of an electronic device 10. The electronic device 10 can be, but is not limited to, a notebook computer, a tablet computer, a gaming device, a DVD player, a radio, a television, a personal digital assistant (PDA), a smart phone, or any other type of portable or non-portable electronic device.

The electronic device 10 includes a cover member 20 rotatably coupled to a base member 30 to enable variable positioning of the cover member 10 relative to the base member 30. One or more magnetic locks 34 are located on a working surface 32 of the base member 30. In the illustrated embodiment, the magnetic lock 34 is located adjacent to a corner of the working surface of the base member 30.

The electronic device 10 further includes a touch-sensitive bar 38 located on a side surface 36 of the base member 30. The touch-sensitive bar 38 may detect and recognize touch gestures input by a user of the electronic device 10. The touch-sensitive bar 38 includes a touch-sensitive surface. In one embodiment, the touch-sensitive surface of the touch-sensitive bar 38 is made from carbon nanotubes. The touch-sensitive bar 38 is elongated in a lengthwise direction of the side surface 36 of the base member 30. In one embodiment, an area of the touch-sensitive bar 38 is substantially the same as an area of the side surface 36 of the base member 30.

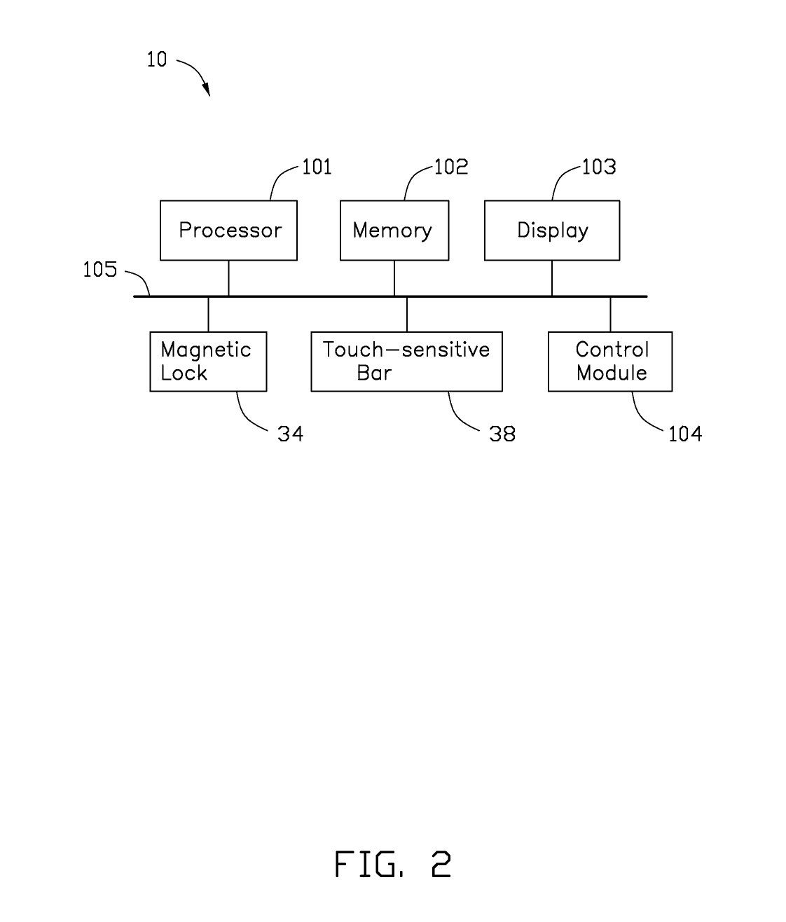

FIG. 2 shows a block diagram of an embodiment of the electronic device 10. The electronic device 10 further includes at least one processor 101, a suitable amount of memory 102, a display 103, and a control module 104. Of course, the electronic device 10 may include additional elements, components, modules, and be functionality configured to support various features that are unrelated to the subject matter described here. In practice, the elements of the electronic device 10 may be coupled together via a bus or any suitable interconnection architecture 105.

The processor 101 may be implemented or performed with a general purpose processor, a content addressable memory, a digital signal processor, an application specific integrated circuit, a field programmable gate array, any suitable programmable logic device, discrete gate or transistor logic, discrete hardware components, or any combination designed to perform the functions described here.

The memory 102 may be realized as RAM memory, flash memory, EPROM memory, EEPROM memory, registers, a hard disk, a removable disk, a CD-ROM, or any other form of storage medium known in the art. The memory 102 is coupled to the processor 101 such that the processor 101 can read information from, and write information to, the memory 102. The memory 102 can be used to store computer-executable instructions. The computer-executable instructions, when read and executed by the processor 101, cause the electronic device 10 to perform certain tasks, operations, functions, and processes described in more detail herein.

The display 103 is suitably configured to enable the electronic device 10 to render and display various screens, GUIs, GUI control elements, menus, texts, or images, for example. Of course, the display 103 may also be utilized for the display of other information during the operation of the electronic device 10, as is well understood. The display 103 can be located in the cover member 20 or the base member 30.

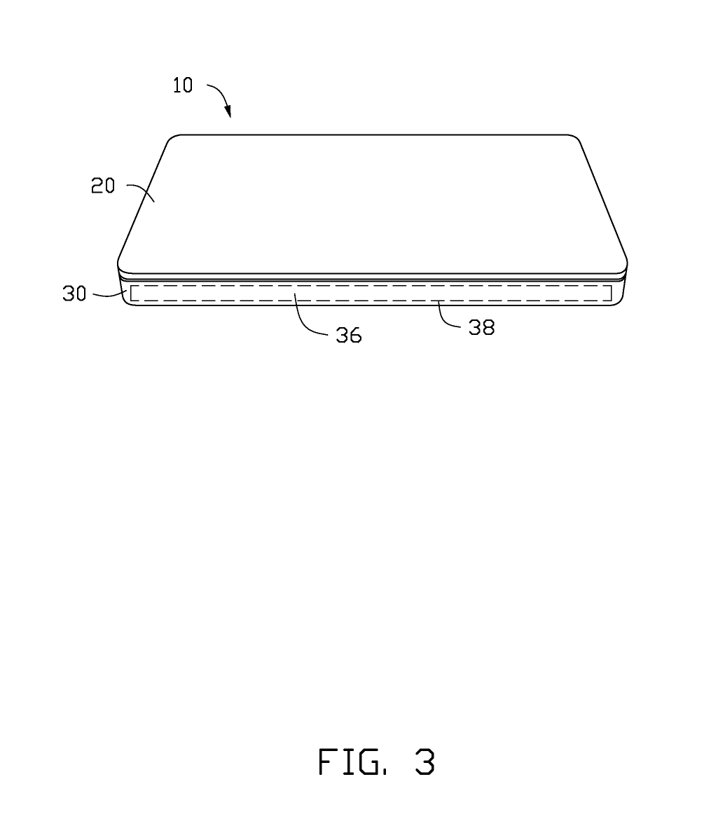

FIG. 3 shows that, when the cover member 20 and the base member 30 are closed, the control module 104 may control the magnetic lock 34 to provide a magnetic attraction between the cover member 20 and the base member 30. Thus, the cover member 20 is attached to the base member 30.

When the touch-sensitive bar 38 detects a touch gesture input by a user and the touch gesture matches a predefined touch gesture, the control module 104 may control the magnetic lock 34 to release the magnetic attraction between the cover member 20 and the base member 30. Thus, the cover member 20 and the base member 30 are capable of being separated. When the touch gesture does not match the predefined touch gesture, the control module 104 may control the magnetic lock 34 to maintain the magnetic attraction between the cover member 20 and the base member 30.

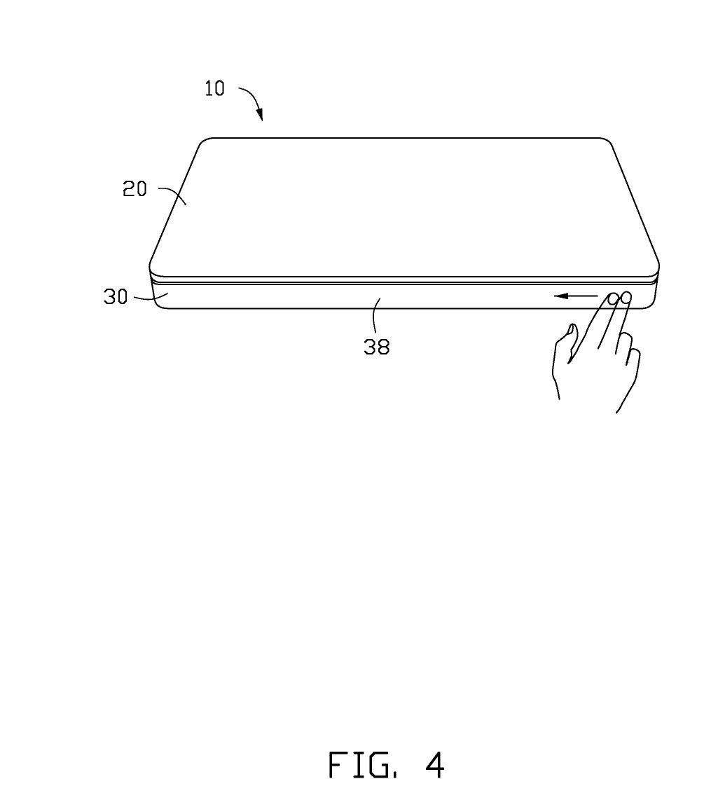

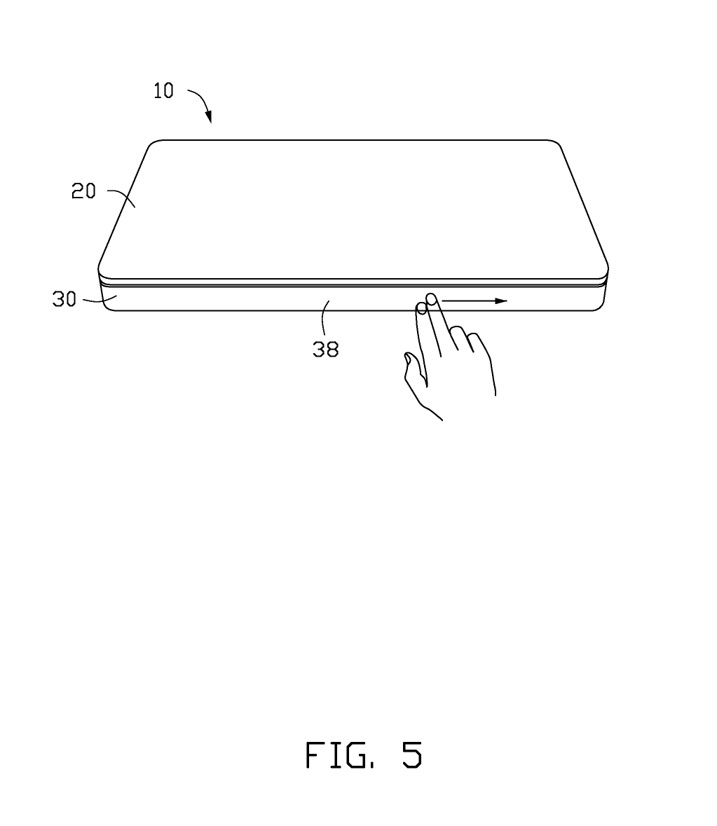

In one embodiment, the predefined touch gesture may include a slide touch made along a lengthwise direction of the touch-sensitive bar. FIG. 4 shows that, when the user makes a right-to-left slide touch with respect to the touch-sensitive bar 38, the control module 104 controls the magnetic lock to release the magnetic attraction between the cover member 20 and the base member 30. FIG. 5 shows that, when the user makes a left-to-right slide touch with respect to the touch-sensitive bar 38, the control module 104 controls the magnetic lock 34 to release the magnetic attraction between the cover member 20 and the base member 30.

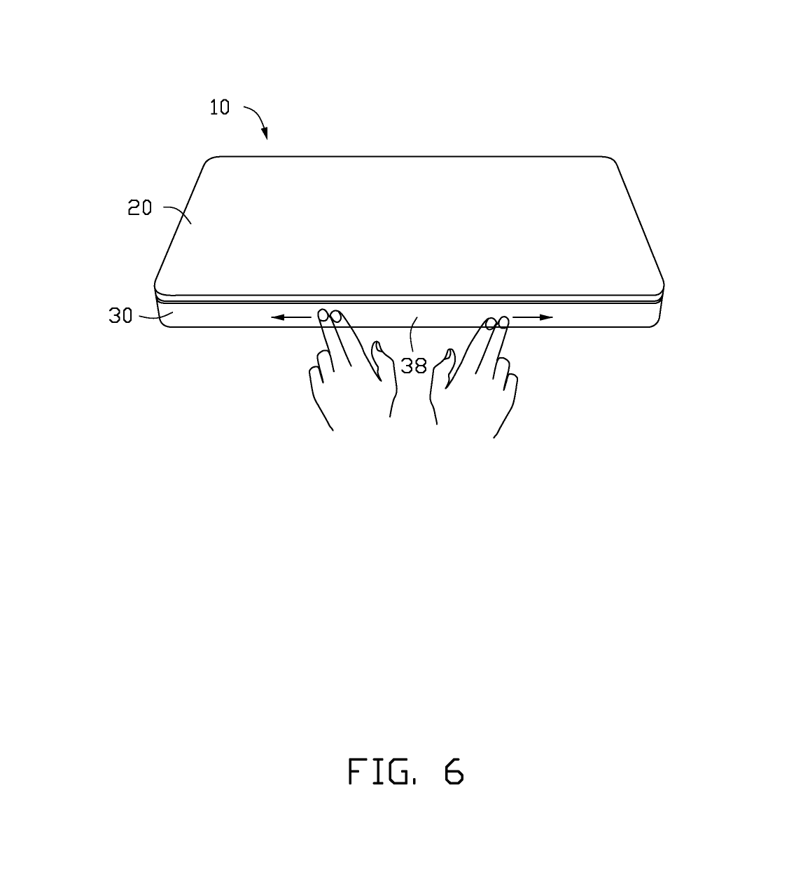

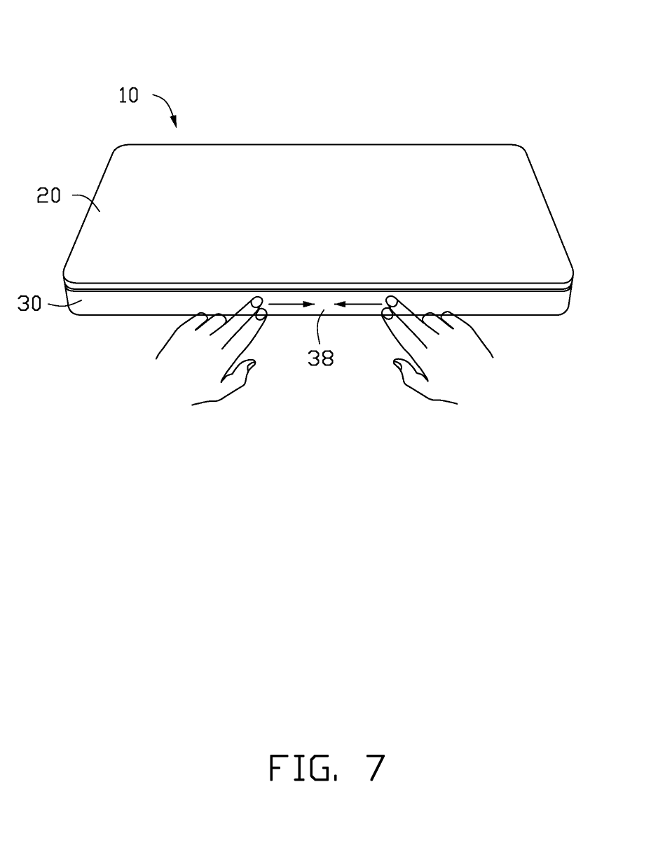

In another embodiment, the predefined touch gesture may include two simultaneous slide touches made along two opposite directions with respect to the touch-sensitive bar 38. FIGS. 6 and 7 show two examples illustrating that, when the user simultaneously makes a right-to-left slide touch and a left-to-right slide touch with respect to the touch-sensitive bar 38, the control module 104 controls the magnetic lock 34 to release the magnetic attraction between the cover member 20 and the base member 30.

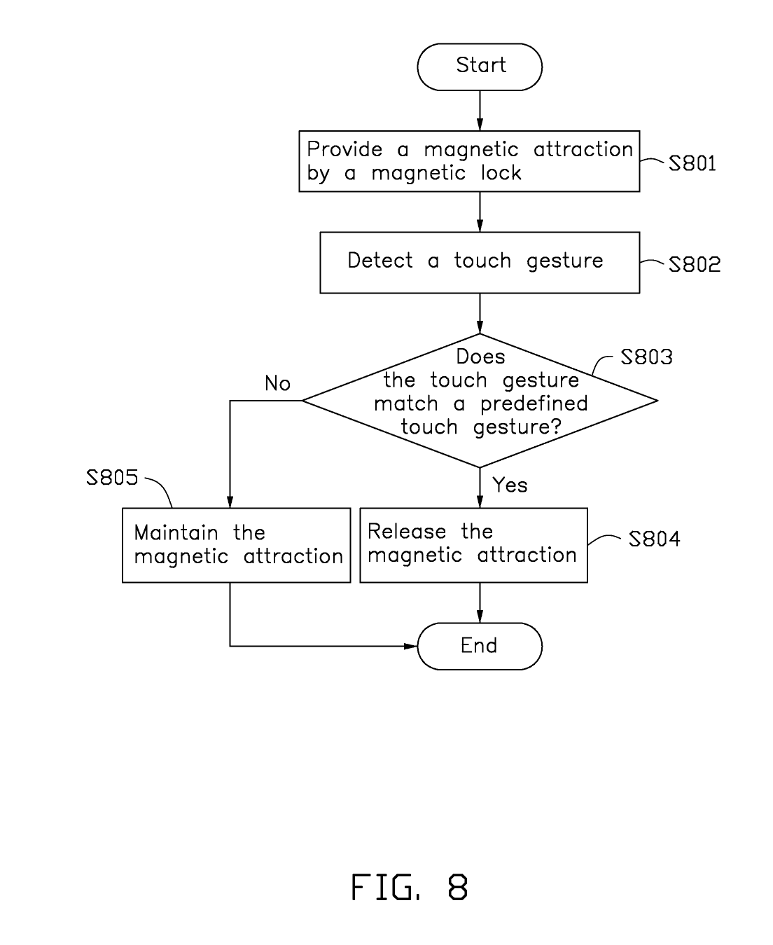

FIG. 8 shows a flowchart of one embodiment of a method for controlling the electronic device 10. The method includes the following steps.

In step S801, when the cover member 20 and the base member 30 are closed, the control module 104 controls the magnetic lock 34 to provide a magnetic attraction between the cover member 20 and the base member 30.

In step S802, the touch-sensitive bar 38 detects a touch gesture input by the user with respect to the touch-sensitive bar 38.

In step S803, the control module 103 determines whether the touch gesture matches a predefined touch gesture. If the touch gesture matches the predefined touch gesture, the flow proceeds to step S804. Otherwise, the flow proceeds to step S805.

In step S804, the control module 104 controls the magnetic lock 34 to release the magnetic attraction between the cover member 20 and the base member 30.

In step S805, the control module 104 controls the magnetic lock 34 to maintain the magnetic attraction between the cover member 20 and the base member 30.

Although numerous characteristics and advantages have been set forth in the foregoing description of embodiments, together with details of the structures and functions of the embodiments, the disclosure is illustrative only, and changes may be made in detail, especially in the matters of arrangement of parts within the principles of the disclosure to the full extent indicated by the broad general meaning of the terms in which the appended claims are expressed.

In particular, depending on the embodiment, certain steps or methods described may be removed, others may be added, and the sequence of steps may be altered. The description and the claims drawn for or in relation to a method may give some indication in reference to certain steps. However, any indication given is only to be viewed for identification purposes, and is not necessarily a suggestion as to an order for the steps.

What is claimed is:

1. An electronic device, comprising:
a base member;
a cover member rotatably connected to the base member;
a magnetic lock located on a working surface of the base member;
a touch-sensitive bar located on a side surface of the base member; and
a control module coupled to the magnetic lock and the touch-sensitive bar;
wherein when the cover member and the base member are closed, the control module is configured to control the magnetic lock to provide a magnetic attraction between the cover member and the base member; when the touch-sensitive bar detects a touch gesture input by a user and the touch gesture matches a predefined touch gesture, the control module is configured to control the magnetic lock to release the magnetic attraction between the cover member and the base member.

2. The electronic device of claim 1, wherein the touch-sensitive bar comprises a touch-sensitive surface of which an area is substantially the same as an area of the side surface of the base member.

3. The electronic device of claim 1, wherein the touch-sensitive bar comprises a touch-sensitive surface made from carbon nanotubes.

4. The electronic device of claim 1, wherein the touch-sensitive bar is elongated in a lengthwise direction of the side surface of the base member.

5. The electronic device of claim 1, wherein the predefined touch gesture comprises a slide touch made along a lengthwise direction of the touch-sensitive bar.

6. The electronic device of claim 1, wherein the predefined touch gesture comprises two simultaneous slide touches made along two opposite directions.

7. The electronic device of claim 1, wherein the side surface of the base member is substantially perpendicular to the working surface of the base member.

8. The electronic device of claim 1, wherein the magnetic lock is located adjacent to a corner of the working surface of the base member.

9. The electronic device of claim 1, wherein when the touch gesture does not match the predefined touch gesture, the control module is configured to control the magnetic lock to maintain the magnetic attraction between the cover member and the base member.

10. A method for controlling an electronic device, the electronic device comprising a base member, a cover member rotatably connected to the base member, a magnetic lock located on a working surface of the base member, and a touch-sensitive bar located on a side surface of the base member, the method comprising:
providing a magnetic attraction between the cover member and the base member by the magnetic lock when the cover member and the base member are closed;
detecting a touch gesture input by a user by the touch-sensitive bar;
determining whether the touch gesture matches a predefined touch gesture;
releasing the magnetic attraction between the cover member and the base member by the magnetic lock when the touch gesture matches the predefined touch gesture.

11. The method of claim 10, wherein the touch-sensitive bar comprises a touch-sensitive surface of which an area is substantially the same as an area of the side surface of the base member.

12. The method of claim 10, wherein the touch-sensitive bar comprises a touch-sensitive surface made from carbon nanotubes.

13. The method of claim 10, wherein the touch-sensitive bar is elongated in a lengthwise direction of the side surface of the base member.

14. The method of claim 10, wherein the predefined touch gesture comprises a slide touch made along a lengthwise direction of the touch-sensitive bar.

15. The method of claim 10, wherein the predefined touch gesture comprises two simultaneous slide touches made along two opposite directions.

16. The method of claim 10, wherein the side surface of the base member is substantially perpendicular to the working surface of the base member.

17. The method of claim 10, wherein the magnetic lock is located adjacent to a corner of the working surface of the base member.

18. The method of claim 10, further comprising maintaining the magnetic attraction between the cover member and the base member by the magnetic lock when the touch gesture does not match the predefined touch gesture.
